(19) United States
(12) Patent Application Publication
(10) Pub. No.: US 2025/0212603 A1
(43) Pub. Date: Jun. 26, 2025

(54) DISPLAY DEVICE AND METHOD OF FABRICATING THE SAME

(71) Applicant: LG Display Co., Ltd., Seoul (KR)

(72) Inventor: Ryuichi SATOH, Kanagawa (JP)

(73) Assignee: LG Display Co., Ltd., Seoul (KR)

(21) Appl. No.: 18/968,959

(22) Filed: Dec. 4, 2024

(30) Foreign Application Priority Data
Dec. 22, 2023 (JP) 2023-216428

(51) Int. Cl. H10K 59/12; H10K 102/00

(52) U.S. Cl. CPC H10K 59/1201; H10K 2102/351

(57) ABSTRACT

A method of fabricating a display device, can include providing a first light emitting element on a first substrate; providing a first elastic member on a second substrate; disposing the first substrate including the first light emitting element over the second substrate including the first elastic member; and transferring the first light emitting element from the first substrate onto the second substrate by irradiating a laser beam, wherein the first elastic member has a storage modulus of 0.01 Pa or more, a loss modulus of 10.0 Pa or more, and a viscosity of 1.8 Pa·sor more. Accordingly, it is possible to provide a process for manufacturing a display device, where misalignment and damage (e.g., breakage) of light emitting elements are suppressed.

### CROSS-REFERENCE TO RELATED APPLICATIONS

The present application claims priority under 35 U.S.C. § 119 to Japanese Patent Application No. 10-2023-216428 filed on Dec. 22, 2023, the contents of which is hereby incorporated by reference in its entirety into the present application for all purposes.

### BACKGROUND

### Technical Field

The present disclosure relates to an organic light emitting device (e.g., alighting device or display device) and a method of fabricating the same.

### Discussion of the Related Art

As demand increases for display devices in various fields, an organic light emitting display device including an organic light emitting diode (OLED) has been a focus of recent research and development. An OLED provides can provide certain advantages over conventional display technologies. For instance, the organic light emitting display device can be operated at a low voltage, consume relatively less power, have excellent colors, be applied to a flexible substrate, and can be provided in a variety of sizes, for a variety of applications. OLED devices can have a wide viewing angle and a high contrast ratio compared to liquid crystal display (LCD) devices and do not require a backlight, making them lightweight and ultra-thin.

Recently, display devices with improved image resolution have been developed by mounting light-emitting elements at high density. In the manufacturing process for such display devices, a process of transferring light-emitting elements installed on a substrate to another substrate is employed in order to mount light-emitting elements at high density.

Japanese Patent Publication No. 2019-530201 discloses a laser lift off (LLO) method for transferring a light-emitting element on a substrate by irradiating a laser beam onto the light-emitting element. However, such methods have shortcomings and limitations. For instance, there can be damage to the light-emitting element during the irradiation of the laser. There is also an issue in the prior art that there can be a misalignment of the light-emitting element during irradiation of the laser.

For at least these reasons, there remains a need in the art to address or obviate the problems and shortcomings of the prior art.

### SUMMARY OF DISCLOSURE

Accordingly, some embodiments of the present disclosure are directed to a display device and a method of fabricating the same that eliminates or substantially obviates one or more of the problems associated with the limitations and disadvantages of the related art.

Some embodiments of the present disclosure provide a display device and a method of fabricating the display device, which are capable of preventing damage on the light-emitting element during the process of irradiating the laser.

Some embodiments of the present disclosure provide a display device and a method of fabricating the display device, which are capable of preventing a misalignment of the light-emitting element during the process of irradiating the laser.

Additional features and aspects are set forth in the description that follows, and will be apparent from the description, or can be learned by the practice of the description provided herein. These features, aspects and embodiments may optionally be combined. Other features and aspects of the present disclosure concepts can be realized and attained by the structure particularly pointed out in the written description, or derivable therefrom, and the claims hereof as well as the appended drawings.

To achieve these and other advantages in accordance with the purpose of the present disclosure, some embodiments relate to a method of fabricating a display device comprising: forming a first light emitting element on a first substrate; forming a first elastic member on a second substrate; disposing the first substrate including the first light emitting element over the second substrate including the first elastic member; and transferring the first light emitting element from the first substrate onto the second substrate by irradiating a laser beam, wherein the first elastic member has a storage modulus of 0.01 Pa or more, a loss modulus of 10.0 Pa or more, and a viscosity of 1.8 Pa·sor more.

In some aspects, the disclosure relates to a method for reducing misalignment and damage of an LED element during manufacture of a display device, comprising: forming a first light emitting element on a first substrate; disposing a first elastic member on a second substrate; curing the first elastic member on the second substrate; disposing the first substrate including the first light emitting element over the second substrate including the first elastic member; and transferring the first light emitting element from the first substrate onto the second substrate by irradiating a laser beam, wherein the first elastic member before the curing process has a storage modulus of 0.01 Pa or more, a loss modulus of 10.0 Pa or more, and a viscosity of 1.8 Pa s or more, and wherein the first elastic member after the curing process has a storage modulus of 0.01 Pa or more and a loss modulus of 10.0 Pa or more.

Other embodiments of the present disclosure include a display device comprising: a substrate; an elastic member on the substrate; and a light emitting element on the elastic member, wherein the elastic member has a storage modulus of 0.01 Pa or more, a loss modulus of 10.0 Pa or more.

It is to be understood that both the foregoing general description and the following detailed description are exemplary and explanatory and are not intended to be limiting.

### BRIEF DESCRIPTION OF THE DRAWINGS

The accompanying drawings illustrate some embodiments of the present disclosure and together with the description serve to explain principles of the present disclosure.

FIG. 1 is a schematic block diagram of a display device according to a first embodiment of the present disclosure.

FIG. 2 is a schematic cross-sectional view of a display device according to the first embodiment of the present disclosure.

FIGS. 3A to 3D are schematic views illustrating a method of fabricating a display device according to the first embodiment of the present disclosure.

FIGS. 4A to 4G are schematic views illustrating another method of fabricating a display device according to the first embodiment of the present disclosure.

FIG. 5 is a schematic view illustrating misalignment of an LED in a display device according to the first embodiment of the present disclosure.

FIG. 6 is a schematic cross-sectional view of a display device according to a second embodiment of the present disclosure.

FIGS. 7A to 7H are schematic views illustrating a method of fabricating a display device according to the second embodiment of the present disclosure.

FIGS. 8A to 8E are schematic views illustrating a method of fabricating a display device according to a third embodiment of the present disclosure.

FIGS. 9A to 9G are schematic views illustrating a method of fabricating a display device according to a fourth embodiment of the present disclosure.

### DETAILED DESCRIPTION OF THE EMBODIMENTS

Reference will now be made in detail to aspects of the present disclosure, examples of which can be illustrated in the accompanying drawings. Elements with common functions throughout each drawing are assigned the same symbol, and overlapping descriptions can be omitted or simplified.

### A First Embodiment

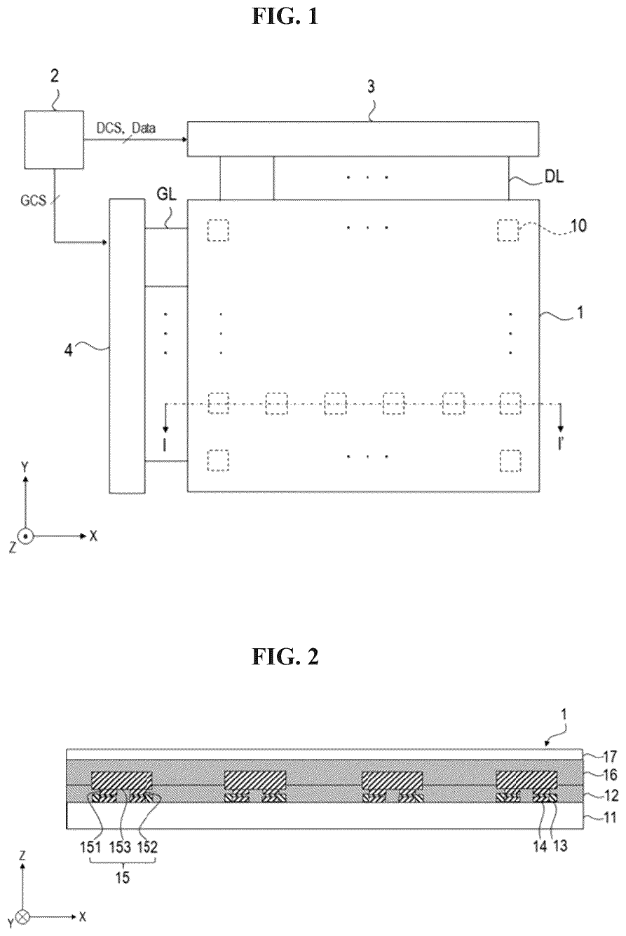

FIG. 1 is a schematic block diagram of a display device according to a first embodiment of the present disclosure. The display device according to this embodiment can be a television display, a computer monitor, a smartphone, a tablet computer, a signage, a flexible display, etc. The display device includes a display panel 1, a controller 2, a data driver 3 and a gate driver 4. In FIG. 1, the horizontal direction of the display panel 1 is defined as an X direction, the vertical direction of the display panel 1 is defined as a Y direction, and the direction perpendicular to the display surface of the display panel 1 is defined as a Z direction.

The display panel 1 can be a light-emitting diode (LED) panel. The display panel 1 can include a plurality of pixels 10 arranged in an array shape, and each pixel 10 includes a micro-LED. The display panel 1 displays an image based on a signal provided from the controller 2.

The controller 2 controls a timing of supplying an image data to the display panel 1. The controller 2 receives various timing signals including a main clock signal, a horizontal synchronization signal, a vertical synchronization signal and a data enable signal from the host system. The timing controller 2 generates a data signal “Data” and a data control signal “DCS” and outputs them to the data driver 3. In addition, the controller 2 generates a gate control signal “GCS” and outputs it to the gate driver 4.

The data driver 3 is connected to the display panel 1 through a plurality of data lines DL. The data driver 3 converts the data signal “data” from a digital signal to an analog signal based on the data control signal “DCS”. The data driver 3 supplies a data signal to the plurality of pixels 10 of the display panel 1 through the plurality of data lines DL.

The gate driver 4 is connected to the display panel 1 through a plurality of gate lines GL. The gate driver 4 generates a gate signal based on the gate control signal “GCS”. The gate driver 4 sequentially scans the plurality of gate lines GL and supplies a gate signal to the plurality of pixels 10 of the display panel 1.

Each of the controller 2, data driver 3 and gate driver 4 can include one or more semiconductor integrated circuits. In addition, some or all of the controller 2, the data driver 3 and the gate driver 4 can be integrated as a single semiconductor integrated circuit.

FIG. 2 is a schematic cross-sectional view of a display device according to the first embodiment of the present disclosure. FIG. 2 is a schematic cross-sectional view taken along the line I-I′ in FIG. 1. In addition, for simplicity of explanation, only four LED elements 15 are shown in FIG. 2 and the following description. The display panel 1 includes a substrate 11, an elastic member 12, a pad 13, a connection member 14, an LED element 15, an insulating layer 16 and a glass substrate 17.

The substrate 11 is made of a rigid material such as glass. In addition, the substrate 11 can be a flexible substrate that can expand and contract. When the substrate 11 is a flexible substrate, the substrate 11 can be made of plastic such as polyimide or polyester. The substrate 11 includes a thin film transistor (TFT). For example, the TFT can be disposed on the substrate 11. The TFT constitutes the pixel circuit of the pixel 10.

The elastic member 12 is installed on the substrate 11. For example, the elastic member 12 can be disposed to cover the TFT. In order to suppress misalignment and damage of the LED element 15, the elastic member 12 can have a storage modulus of 0.01 Pa or more, a loss modulus of 10.0 Pa or more and a viscosity of 1.8 Pa s or more before a curing process. The elastic member 12 can have a thickness of 10 μm or less, preferably 1 μm or more and 5 μm or less. A thickness of elastic member 12 can be equal to or smaller than a height of the LED element 15. The elastic member 12 can have a storage modulus of 0.01 Pa or more and a loss modulus of 10.0 Pa or more after a curing process.

In some embodiments, the elastic member 12 before a curing process can have (i) a storage modulus of about 0.01 to 10 Pa, preferably about 0.01 to 5 Pa, most preferably about 0.01 to 1 Pa, (ii) a loss modulus of about 10.0-100 Pa, preferably about 10-75 Pa, most preferably about 10-50 Pa, and (iii) a viscosity of about 1.8-5.0 Pa s, preferably about 1.8-3.0 Pa s, most preferably about 1.8-2.5 Pa s. In some embodiments, the elastic member 12 after a curing process can have (i) a storage modulus of about 0.01 to 10 Pa, preferably about 0.01 to 5 Pa, most preferably about 0.01 to 1 Pa, (ii) a loss modulus of about 10.0-100 Pa, preferably about 10-75 Pa, most preferably about 10-50 Pa.

Some embodiments relate to a method for transferring a light emitting element, where the method comprises providing a first light emitting element on a first substrate; providing a first elastic member on a second substrate; disposing the first substrate including the first light emitting element over the second substrate including the first elastic member, wherein the elastic member faces the first light emitting element; and transferring the first light emitting element from the first substrate onto the second substrate, wherein the first elastic member has a storage modulus of 0.01 Pa or more, a loss modulus of 10.0 Pa or more, and a viscosity of 1.8 Pa s or more.

Other embodiments relate to a method for transferring a plurality of light emitting element, where the method comprises providing a first light emitting element on a first substrate; providing a first elastic member on a second substrate; disposing the first substrate including the first light emitting element over the second substrate including the first elastic member, wherein the elastic member faces the first light emitting element; and transferring the first light emitting element from the first substrate onto the second substrate, wherein the first elastic member has a storage modulus of 0.01 Pa or more, a loss modulus of 10.0 Pa or more, and a viscosity of 1.8 Pa s or more.

In some embodiments, the laser beam source can be an excimer laser, a solid-state laser, or the like. The transferring comprises irradiation on the first substrate by a laser beam, wherein the laser beam is a gas laser (e.g., CO2), a solid-state laser (e.g., Nd:YAG), an excimer laser (e.g., KrF), a diode laser (e.g., semiconductor), a fiber laser, a dye laser, or an ion laser.

In some embodiments, the laser beam is operated using at least one of the following parameters: a wavelength from about 300 nm to about 500 nm; a pulse duration of about 10-100 ns, a pulse energy of about 1-50 μJ per pulse, a spot size of 5-30 μm, a repetition rate of 1-10 Hz.

In some embodiments, the first light emitting element is an standard light emitting diode (LED), a miniature LED, a micro LED, a high-power LED, a RGB (red green blue) LED, a surface-mount LED, a chip-on-board LED, an organic LED (OLED), an infrared (IR) LED, an ultraviolet (UV) LED, or a flash LED.

Some embodiments, relate to a finished substrate produced by the methods described herein, wherein a plurality of light emitting elements are transferred, as well as to a display device comprising the finished substrate thereof.

The elastic member 12 can include a thermosetting resin. For example, thermosetting resin can include at least one of an acrylic compound, a silicone compound, an epoxy compound, an epoxyacrylate compound, an oxetane compound, an episulfide compound, an acrylic silicone compound, a methacrylic compound, a phenol compound, an amino compound, an unsaturated polyester compound and a polyurethane compound.

The acrylic compound can be ethoxylated bisphenol A diacrylate represented by Formula 1. In Formula 1, R independently represents an organic group, and each of m and n independently represents an integer of 0 or more.

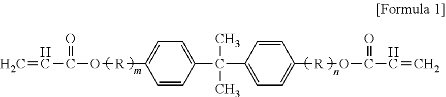

In Formula 1, the organic group can be selected from the group consisting of a structure of Formula 1-1, a structure of Formula 1-2, a substituted or unsubstituted C6 to C30 arylene group and a substituted or unsubstituted C3 to C30 heteroarylene group.

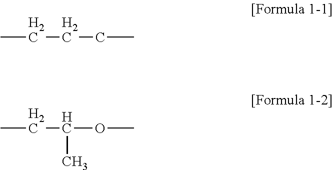

In the present disclosure, while not being limiting, a substituent of an alkyl group, a cycloalkyl group, an aryl group, a heteroaryl group and an arylamino group can be at least one of a substituted or unsubstituted C1 to C10 alkyl group, a substituted or unsubstituted C3 to C30 cycloalkyl group, a substituted or unsubstituted C6 to C30 aryl group and a substituted or unsubstituted C3 to C30 heteroaryl group.

In the present disclosure, while not being limiting, a C1 to C30 alkyl group can be selected from the group consisting of methyl, ethyl, propyl and butyl, e.g., tert-butyl or isobutyl.

In the present disclosure, while not being limiting, a C3 to C30 cycloalkyl group can be selected from the group consisting of cyclopropyl, cyclobutyl, cyclopentyl, cyclohexyl, and adamantanyl.

In the present disclosure, while not being limiting, a C6 to C30 aryl group can be selected from the group consisting of phenyl, biphenyl, terphenyl, naphthyl, anthracenyl, pentanenyl, indenyl, indenoindenyl, heptalenyl, biphenylenyl, indacenyl, phenanthrenyl, benzophenanthrenyl, dibenzophenanthrenyl, azulenyl, pyrenyl, fluoranthenyl, triphenylenyl, chrysenyl, tetraphenyl, tetracenyl, picenyl, pentaphenyl, pentacenyl, fluorenyl, indenofluorenyl and spiro-fluorenyl.

In the present disclosure, while not being limiting, a C6 to C30 arylene group can be selected from the group consisting of phenylene, biphenylene, terphenylene, naphthylene, anthracenylene, pentanenylene, indenylene, indenoindenylene, heptalenylene, biphenylenylene, indacenylene, phenanthrenylene, benzophenanthrenylene, dibenzophenanthrenylene, azulenylene, pyrenylene, fluoranthenylene, triphenylenylene, chrysenylene, tetraphenylene, tetracenylene, picenylene, pentaphenylene, pentacenylene, fluorenylene, indenofluorenylene and spiro-fluorenylene.

In the present disclosure, while not being limiting, a C3 to C30 heteroaryl group can be selected from the group consisting of pyrrolyl, pyridinyl, pyrimidinyl, pyrazinyl, pyridazinyl, triazinyl, tetrazinyl, imidazolyl, pyrazolyl, indolyl, isoindolyl, indazolyl, indolizinyl, pyrrolizinyl, carbazolyl, benzocarbazolyl, dibenzocarbazolyl, indolocarbazolyl, indenocarbazolyl, benzofurocarbazolyl, benzothienocarbazolyl, quinolinyl, isoquinolinyl, phthalazinyl, quinoxalinyl, cinnolinyl, quinazolinyl, quinolizinyl, quinolinyl, purinyl, phthalazinyl, quinoxalinyl, benzoquinolinyl, benzoisoquinolinyl, benzoquinazolinyl, benzoquinoxalinyl, acridinyl, phenanthrolinyl, perimidinyl, phenanthridinyl, pteridinyl, naphtharidinyl, furanyl, oxazinyl, oxazolyl, oxadiazolyl, triazolyl, dioxinyl, benzofuranyl, dibenzofuranyl, thiopyranyl, xanthenyl, chromanyl, isochromanyl, thioazinyl, thiophenyl, benzothiophenyl, dibenzothiophenyl, difuropyrazinyl, benzofurodibenzofuranyl, benzothienobenzothiophenyl, benzothienodibenzothiophenyl, benzothienobenzofuranyl, and benzothienodibenzofuranyl.

In some embodiments, while not being limiting, a C3 to C30 heteroarylene group can be selected from the group consisting of pyrrolylene, pyridinylene, pyrimidinylene, pyrazinylene, pyridazinylene, triazinylene, tetrazinylene, imidazolylene, pyrazolylene, indolylene, isoindolylene, indazolylene, indolizinylene, pyrrolizinylene, carbazolylene, benzocarbazolylene, dibenzocarbazolylene, indolocarbazolylene, indenocarbazolylene, benzofurocarbazolylene, benzothienocarbazolylene, quinolinylene, isoquinolinylene, phthalazinylene, quinoxalinylene, cinnolinylene, quinazolinylene, quinolizinylene, quinolinylene, purinylene, phthalazinylene, quinoxalinylene, benzoquinolinylene, benzoisoquinolinylene, benzoquinazolinylene, benzoquinoxalinylene, acridinylene, phenanthrolinylene, perimidinylene, phenanthridinylene, pteridinylene, naphtharidinylene, furanylene, oxazinylene, oxazolylene, oxadiazolylene, triazolylene, dioxynylene, benzofuranyenel, dibenzofuranylene, thiopyranylene, xanthenylene, chromanylene, isochromanylene, thioazinylene, thiophenylene, benzothiophenylene, dibenzothiophenylene, difuropyrazinylene, benzofurodibenzofuranylene, benzothienobenzothiophenylene, benzothienodibenzothiophenylene, benzothienobenzofuranylene, and benzothienodibenzofuranylene.

For example, in Formula 1, each of m and n can be independently an integer of 0 to 10. In some embodiments, each of m and n can be independently 0 or 1.

In some embodiments, R can be represented by Formula 1-1, and a summation of m and n can be 2, 3, 4, 10, 20 or 30.

In some embodiments, R can be represented by Formula 1-2, and a summation of m and n can be 3.

In some embodiments, R can be independently selected from the group consisting of phenylene, naphthylene and triazinylene.

For example, the acrylic compound represented by Formula 1 can be a compound in Formula 1-3.

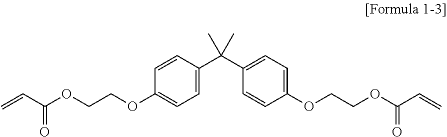 [SMILES: C=CC(=O)OCCOc1ccc(C(C)(C)c2ccc(OCCOC(=O)C=C)cc2)cc1]

The acrylic compound can be a divinylbenzylfluorene acrylic compound represented by Formula 2. In Formula 2, each of R^{1a}, R^{1b}, R^{2a}, R^{2b}, R^{3a}, R^{3b}, R^{4a} and R^{4b} independently represents a hydrogen atom or an organic group, and each of k1, k2, m1, m2, n1, n2, p1 and p2 independently represents an integer of 0 or more.

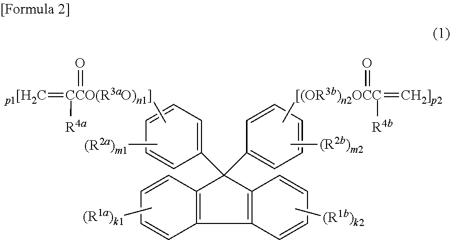

In Formula 2, each of R^{1a}, R^{1b}, R^{2a}, R^{2b}, R^{4a} and R^{4b} can be independently selected from the group consisting of a substituted or unsubstituted C1 to C20 alkyl group, a substituted or unsubstituted C3 to C30 cycloalkyl group, a substituted or unsubstituted C6 to C30 aryl group and a substituted or unsubstituted C3 to C30 heteroaryl group, and each of R^{3a} and R^{3b} can be independently selected from the group consisting of a substituted or unsubstituted C1 to C20 alkylene group, a substituted or unsubstituted C3 to C30 cycloalkylene group, a substituted or unsubstituted C6 to C30 arylene group and a substituted or unsubstituted C3 to C30 heteroarylene group.

For example, in Formula 2, each of k1, k2, m1, m2, n1, n2, p1 and p2 can be independently an integer of 0 to 10. In some embodiments, each of k1, k2, m1, m2, n1, n2, p1 and p2 can be independently 0 or 1.

In some embodiments, each of R^{1a}, R^{1b}, R^{2a}, R^{2b}, R^{4a} and R^{4b} can be independently selected from the group consisting of methyl, ethyl, tert-butyl, phenyl, naphthyl and biphenyl, and each of R^{3a} and R^{3b} can be independently selected from the group consisting of a substituted or unsubstituted C1 to C20 alkylene group, e.g., ethylene.

For example, the acrylic compound represented by Formula 2 can be a compound in Formula 2-1.

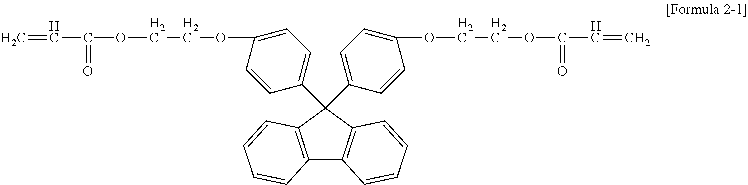 [SMILES: C=CC(=O)OCCOc1ccc(C2(c3ccc(OCCOC(=O)C=C)cc3)c3ccccc3-c3ccccc32)cc1]

The acrylic compound can be tris-(2-acryloxyethyl)isocyanurate represented by Formula 3. In Formula 3, X independently represents a hydrogen atom or an organic group, and each of l, m and n independently represents integers of 0 or more.

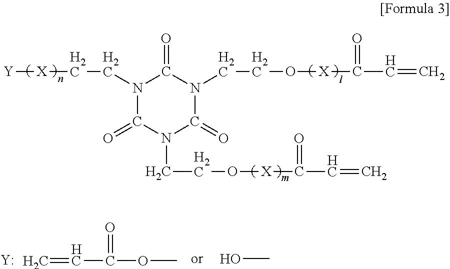

In Formula 1, the organic group can be selected from the group consisting of a structure of Formula 3-1, a substituted or unsubstituted C6 to C30 arylene group and a substituted or unsubstituted C3 to C30 heteroarylene group.

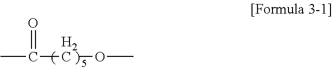

For example, in Formula 3, each of l, m and n can be independently an integer of 0 to 10. In some embodiments, each of l, m and n can be independently 0 or 1.

In some embodiments, each of l, m and n can be 0.

For example, the acrylic compound represented by Formula 3 can be a compound in Formula 3-2.

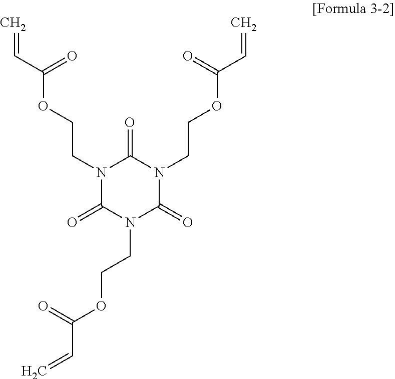 [SMILES: C=CC(=O)OCCn1c(=O)n(CCOC(=O)C=C)c(=O)n(CCOC(=O)C=C)c1=O]

The silicone compound can be an epoxy-modified organosiloxane represented by Formula 4. In Formula 4, each of R₁ and E₁ independently represents a hydrogen atom or an organic group, R₂ represents a single bond or an organic group, Z represents an organic group, and each of l, m, and n independently represents an integer of 0 or more.

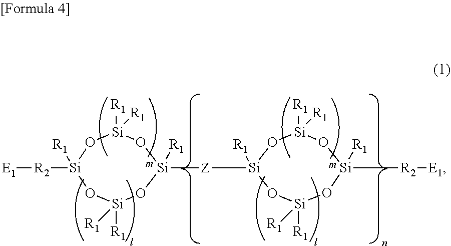

In Formula 4, the organic group being R₁ can be selected from the group consisting of a substituted or unsubstituted C1 to C20 alkyl group, a substituted or unsubstituted C3 to C30 cycloalkyl group, a substituted or unsubstituted C6 to C30 arylene group and a substituted or unsubstituted C3 to C30 heteroarylene group.

R₂ can be a single bond or a substituted or unsubstituted C1 to C20 alkylene group.

R₁ can be selected from a structure of Formula 4-1 to 4-3.

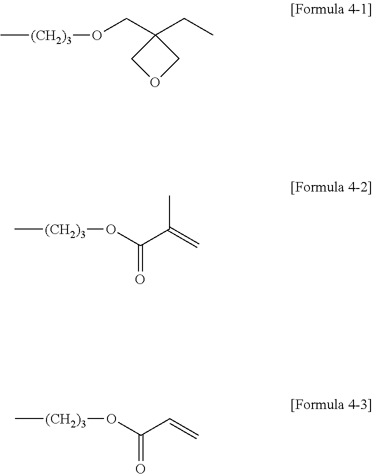

In Formula 4, the organic group can include a trivalent group of a substituted or unsubstituted C6 to C30 aromatic group and a substituted or unsubstituted C3 to C30 heteroaromatic group.

For example, in Formula 4, each of l, m and n can be independently an integer of 0 to 10. In some embodiments, each of l, m and n can be independently 0 or 1.

In some embodiments, Z can be selected from a trivalent group of benzene, triazine and 1,3,5-triazine-2,4,6-triolate.

The silicone compound represented by Formula 4 can be an epoxy-modified organosiloxane represented by Formula 5.

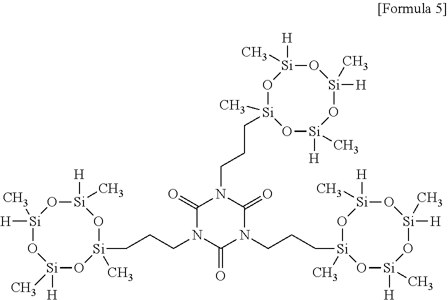 [SMILES: C[SiH]1O[SiH](C)O[Si](C)(CCCn2c(=O)n(CCC[Si]3(C)O[SiH](C)O[SiH](C)O[SiH](C)O3)c(=O)n(CCC[Si]3(C)O[SiH](C)O[SiH](C)O[SiH](C)O3)c2=O)O[SiH](C)O1]

The epoxy compound can include at least one of a phenol novolak-type epoxy compound, a cresol novolak-type epoxy compound, a bisphenol A-type epoxy compound, a bisphenol F-type epoxy compound, phenyl glycidyl ether, p-butyl phenol glycidyl ether, triglycidyl isocyanurate, diglycidyl isocyanurate, allyl glycidyl ether and glycidyl methacrylate.

For example, the epoxy compound can be a divinylbenzylfluorene epoxy compound represented by Formula 6. In Formula 6, each of R¹, R², R³ and R⁴ independently represents a hydrogen atom or an organic group, and each of k and m independently represents an integer of 0 or more.

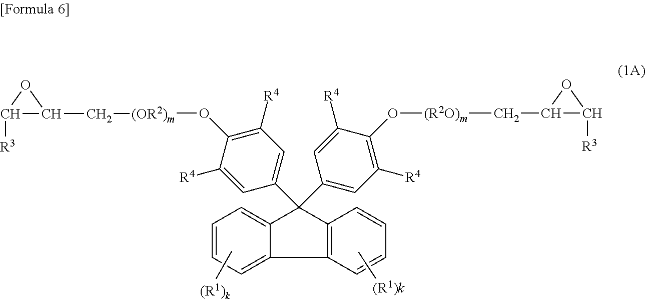

In Formula 6, R¹, R³ and R⁴ can be selected from the group consisting of a substituted or unsubstituted C1 to C20 alkyl group, a substituted or unsubstituted C3 to C30 cycloalkyl group, a substituted or unsubstituted C6 to C30 aryl group and a substituted or unsubstituted C3 to C30 heteroaryl group, and R₂ can be selected from the group consisting of a substituted or unsubstituted C1 to C20 alkylene group, a substituted or unsubstituted C3 to C30 cycloalkylene group, a substituted or unsubstituted C6 to C30 arylene group and a substituted or unsubstituted C3 to C30 heteroarylene group.

For example, in Formula 6, each of k and m can be independently an integer of 0 to 10. In some embodiments, each of k and m can be independently 0 or 1.

For example, the epoxy compound represented by Formula 6 can be a compound in Formula 6-1.

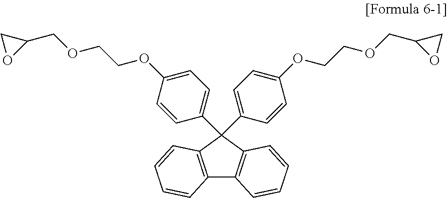 [SMILES: c1ccc2c(c1)-c1ccccc1C2(c1ccc(OCCOCC2CO2)cc1)c1ccc(OCCOCC2CO2)cc1]

In some embodiments, R¹, R², R³ and R⁴ can be independently selected from the group consisting of methyl, ethyl, tert-butyl, phenyl, naphthyl and biphenyl.

The epoxy compound can be a compound, e.g., a bisphenol A diglycidyl ether acrylic acid adduct, represented by Formula 7.

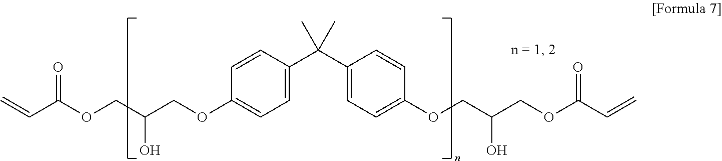

The elastic member 12 can include an ultraviolet (UV) curable resin instead of a thermosetting resin. For example, the UV curable resin can include (meth)acrylate, e.g., at least one of 2-hydroxyethyl (meth)acrylate, 2-hydroxypropyl (meth)acrylate, 2-ethylhexyl (meth)acrylate, ethylene glycol di(meth)acrylate, diethylene glycol di(meth)acrylate, triethylene glycol di(meth)acrylate, tetraethylene glycol di(meth)acrylate, pentaerythritol tri(meth)acrylate, pentaerythritol tetra(meth)acrylate, dipentaerythritol tetra(meth)acrylate, dipentaerythritol hexa(meth)acrylate, or glycerol (meth)acrylate. The “(meth)acrylate” means one or both of acrylate and methacrylate, and (meth)acrylic acid means one or both of acrylic acid and methacrylic acid.

The pad 13 is installed on substrate 11. The pad 13 is embedded in the elastic member 12. The pad 13 can include (or be made of) metal such as aluminum (Al), gold (Au), copper (Cu), and nickel (Ni).

The connection member 14 is installed on the pad 13. The connection member 14 can include a solder-based material. The solder-based material can include at least one of tin (Sn), nickel (Ni), copper (Cu), antimony (Sb), aluminum (Al), zinc (Zn), iron (Fe), gold (Au), silver (Ag), titanium. (Ti), germanium (Ge), tellurium (Te), cobalt (Co), bismuth (Bi), manganese (Mn), chromium (Cr), molybdenum (Mo), palladium (Pd) and indium (In). The connection member 14 can include an organic conductive material or a conductive nanoparticle instead of the solder-based material.

The LED element 15 includes terminals 151 and 152 and a semiconductor layer 153. The LED element 15 is electrically connected to the connection member 14 through the terminals 151 and 152. The LED element 15 is installed on the elastic member 12. Each of the terminal 151 and terminal 152 can include metal such as gold, silver, tin, nickel, and palladium. The semiconductor layer 153 is connected to the terminal 151 and terminal 152. The semiconductor layer 153 is composed of a p-type semiconductor and an n-type semiconductor and functions as an LED. The height of the LED element 15 can be equal to or greater than the thickness of the elastic member 12. The height of the LED element 15 can be 100 μm or less, for example, 1 μm or more and 10 μm or less. The LED element 15 corresponds to a subpixel of the pixel 10. For example, the pixel 10 can include an LED element 15 that emits red light (e.g., a red LED), an LED element 15 that emits green light (e.g., a green LED), and an LED element 15 that emits blue light (e.g., a blue LED). The pixel 10 can include three LED elements (15).

The insulating layer 16 is installed on the elastic member 12 to cover the LED element 15. The insulating layer 16 covers the LED element 15 together with the elastic member 12. The insulating layer 16 can include an inorganic insulating material, e.g., silicon oxide (SiOx) or silicon nitride (SiNx), or an organic insulating material.

The glass substrate 17 is installed on the insulating layer 16. The glass substrate 17 can include an inorganic insulating material, e.g., silicon oxide (SiOx) or silicon nitride (SiNx), or an organic insulating material. The glass substrate 17 has a function to prevent penetration of impurities, e.g., moisture or oxygen, from the outside.

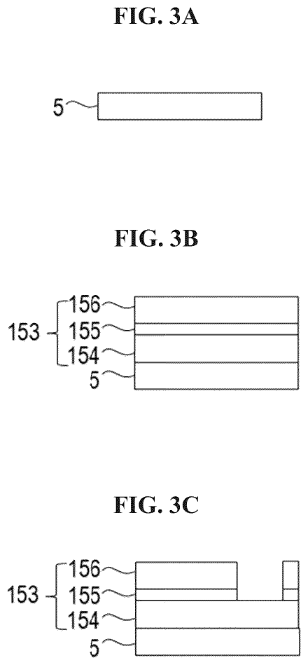

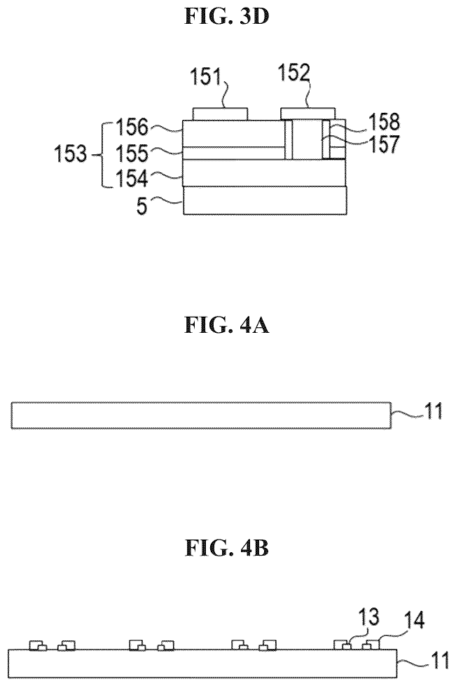

FIGS. 3A to 3D are schematic views illustrating a method of fabricating a display device according to the first embodiment of the present disclosure. FIGS. 3A to 3D show the process of forming the LED element 15 on the wafer 5. In addition, for simplicity of explanation, FIGS. 3A to 3D shows one LED device 15 among a plurality of LED devices 15 formed on the wafer 5.

As shown in FIG. 3A, a wafer 5 is prepared. The wafer 5 can be, for example, a sapphire substrate made of a single crystal of aluminum oxide. The wafer 5 can be manufactured by a known method such as the CZ (CZochralski) method or the Edge-defined Film-fed Growth (EFG) method. In addition, the wafer 5 is installed for each color emitted by the LED element 15. For example, when the display panel 1 has three types of LED elements 15, e.g., a red LED, a green LED and a blue LED, three wafers 5 are prepared to form the LED elements 15 of each color.

As shown in FIG. 3B, a semiconductor layer 153 having a triple-layered structure including an n-type layer 154, a light emitting layer 155 and a p-type layer 156 is formed on the wafer 5. The n-type layer 154 can be formed by adding an n-type impurity, e.g., phosphorus (P) or arsenic (As), to gallium nitride (GaN). The light emitting layer 155 can be formed of indium gallium nitride (InGaN) or the like. The p-type layer 156 can be formed by adding a p-type impurity, e.g., boron (B) or aluminum, to gallium nitride. The n-type layer 154, the light emitting layer 155 and the p-type layer 156 can be formed by well-known methods such as the liquid phase epitaxy (LPE) method or the metal organic vapor phase epitaxy (MOVPE) method.

As shown in FIG. 3C, a part of the light emitting layer 155 and the p-type layer 156 is removed (e.g., etched) to form a first through-hole. A part of the n-type layer 154 is exposed through first the through-hole. The light emitting layer 155 and the p-type layer 156 can be removed by known methods such as photolithography, electron beam lithography or laser patterning.

As shown in FIG. 3D, an insulating layer 158 is buried (formed) in the first through-hole. The insulating layer 158 can include (e.g., be made of) an inorganic insulating material, e.g., silicon oxide (SiOx) or silicon nitride (SiNx), or an organic insulating material. Next, a part (e.g., a center) of the insulating layer 158 in the first through-hole is removed (e.g., etched) to form a second through-hole penetrating the insulating layer 158. A part of the n-type layer 154 is exposed through the second through-hole. After the second through-hole is formed, the insulating layer 158 can be formed at a side surface of the light emitting layer 155 and the p-type layer 156 and surround the second through-hole. Next, a through electrode 157 is formed in the second through hole. The through electrode 157 can include metal such as gold, silver, tin, nickel, or palladium. Next, a terminal 151 (e.g., a first terminal) is formed on the p-type layer 156, and a terminal 152 (e.g., a second terminal) is formed on the through electrode 157. An entirety of a bottom surface of the terminal 151 can contact the p-type layer 156. A part, e.g., a center, of a bottom surface of the terminal 152 can contact the through electrode 157, while a part, e.g., an edge, of the bottom surface of the terminal 152 can contact the insulating layer 158.

As a result, the LED element 15 including the terminals 151 and 152, the n-type layer 154, the light emitting layer 155, the p-type layer 156, the through electrode 157 and the insulating layer 158 is formed on the wafer 5. The LED element 15 formed in this way is transferred to the substrate 11 in the manufacturing process of the display panel 1 described later.

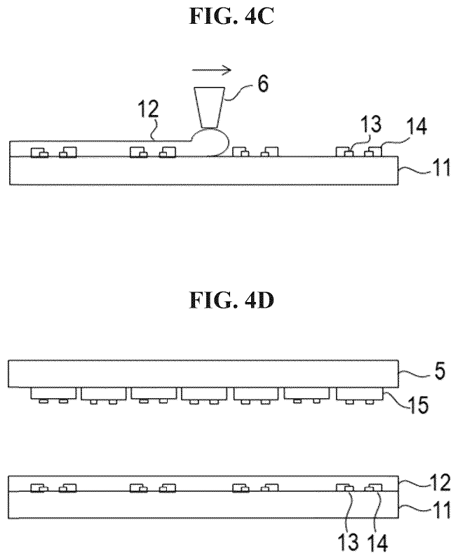

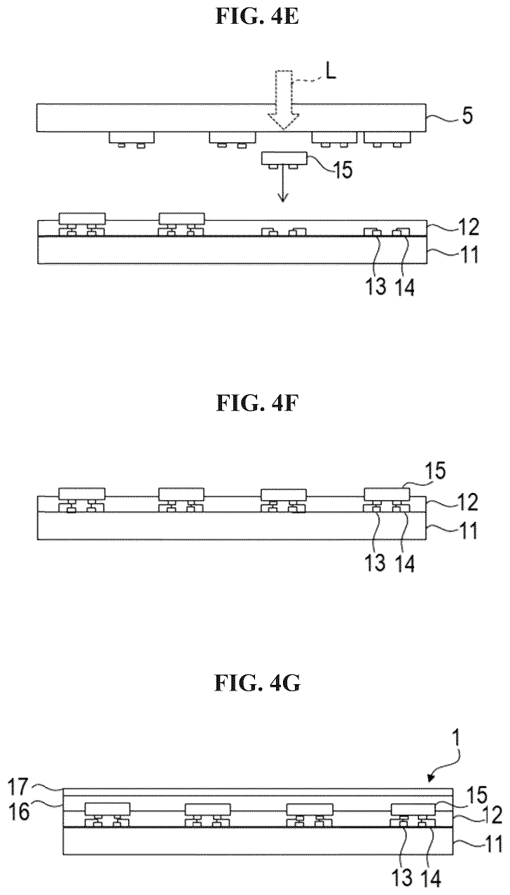

FIGS. 4A to 4G are schematic views illustrating another method of fabricating a display device according to the first embodiment of the present disclosure. FIGS. 4A to 4G show processes forming an elastic member 12, a pad 13, a connection member 14, an LED element 15, an insulating layer 16 and glass substrate 17 on a substrate 11.

As shown in FIG. 4A, a substrate 11 is prepared. Next, as shown in FIG. 4B, a pad 13 and the connection member 14 are sequentially formed on the substrate 11. The pad 13 and the connecting member 14 can be formed by known methods such as photolithography, electron beam lithography and laser patterning.

As shown in FIG. 4C, an elastic member 12 is formed on the substrate 11. For example, the elastic member 12 can be formed by coating a material using a nozzle 6. In FIG. 4C, the arrow indicates the direction in which the nozzle 6 moves. The thickness of the elastic member 12 is set to a predetermined thickness. The predetermined thickness can be 10 μm or less, preferably 1 μm or more and 5 μm or less. In addition, FIG. 4C shows an example of coating the elastic member 12 while the nozzle 6 moves on the substrate 11, but it is not limited thereto. For example, the elastic member 12 can be formed while moving the substrate 11 with respect to the fixed nozzle 6.

As shown FIG. 4D, the wafer 5 is disposed to be opposed to the substrate 11 at a predetermined interval so that the LED element 15 on the wafer 5 and the elastic member 12 on the substrate 11 face to each other. The wafer 5 and the substrate 11 are positioned by a stage that can be raised and lowered. The gap distance between the wafer 5 and the substrate 11 can be set to a predetermined distance by raising and lowering the stage.

As shown in FIG. 4E, by the LLO method, laser beam L from a laser beam source is irradiated from the back of the wafer 5 to the LED element 15, and the LED element 15 is transferred to the substrate 11. The laser beam source can be an excimer laser, a solid-state laser, or the like. The laser beam L is absorbed by gallium nitride in the n-type layer 154 of the LED element 15, and the gallium nitride is decomposed into gallium and nitrogen. When the portion of the n-type layer 154 in contact with the wafer 5 is decomposed, the LED element 15 is peeled off from the wafer 5. The peeled LED element 15 flies toward the elastic member 12. The LED element 15 is held by the elastic member 12, and the terminals 151 and 152 of the LED element 15 are electrically connected to the pad 13 through the connection member 14. As described above, the LED elements 15 can be transferred from different wafers 5 for each color of the LED elements 15.

As shown in FIG. 4F, after the transfer of all LED elements 15 is completed, the wafer 5 is separated (or released) from the substrate 11. In this way, the LED element 15 is formed on the substrate 11. In the display device of the present disclosure, the elastic resin 12 is formed on the pad 13 and the connection member 14, and the LED element 15 is transferred into the elastic member 12. As a result, a portion of the elastic member 12 is presented between the pads 13 for a single LED element 15 and/or between the connection members 14 for a single LED element 15. Namely, a portion of the elastic member 12 is presented in a space formed by the pads 13 and the LED element 15 and/or in a space formed by the connection members 14 and the LED element 15.

As shown in FIG. 4G, the elastic member 12 is cured by heat or the like, and an insulating layer 16 and a glass substrate 17 are formed in that order on the elastic member 12. Namely, the insulating layer 16 is positioned between the LED member 15 and the glass substrate 17 and between the elastic member 12 and the glass substrate 17. The elastic member 12 can be heated using any heat source such as a hot plate, an infrared lamp, or an infrared laser. As described above, the display panel 1 is manufactured.

In addition, the melting point of the connection member 14 can be equal to or lower than the heating temperature at which the elastic member 12 is thermally cured. In this case, the connection member 14 is melted when the elastic member 12 is thermally cured so that the electrical connection between the pad 13 and the terminals 151 and 152 of the LED element 15 can be enhanced.

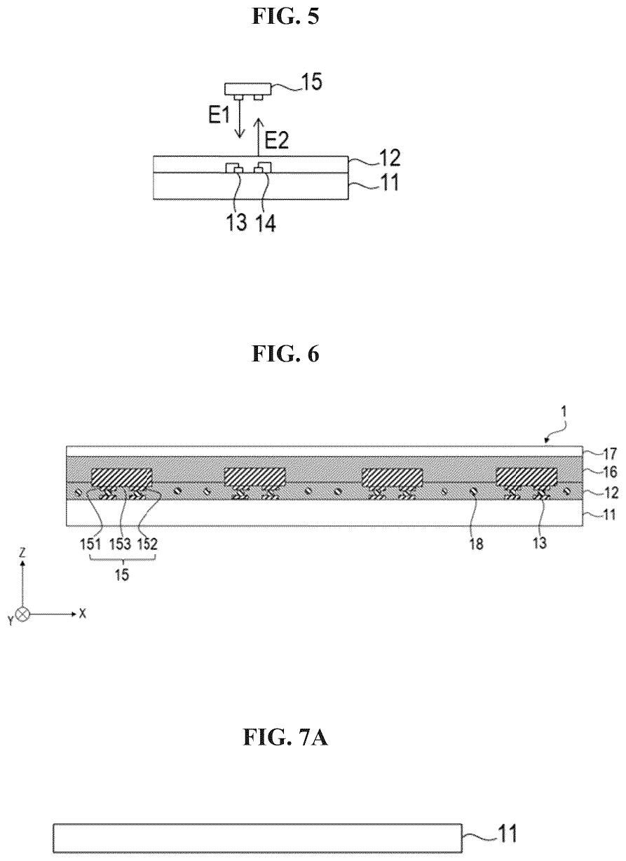

In the display device of this embodiment, the misalignment and the damage of the LED element 15 are suppressed by setting the elastic modulus and viscosity of the elastic member 12 to predetermined values. FIG. 5 is a schematic view illustrating misalignment of the LED element 15 according to this embodiment. The LED element 15 receives kinetic energy E1 by irradiation of the laser beam and flies toward the elastic member 12. For example, if the LED element 15 has a size of 20×30 μm and a thickness of 10 μm, the LED element 15 can fly at a speed of 80 m/s (288 km/h). When the LED element 15 collides with the elastic member 12, the LED element 15 receives kinetic energy E2 in the opposite direction to the kinetic energy E1 as a repulsive force due to the elastic member 12. If the elastic modulus and viscosity of the elastic member 12 are not appropriate, the elastic member 12 cannot sufficiently absorb the kinetic energy E1 of the LED element 15. As a result, the LED element 15 receives large kinetic energy E2, and the misalignment of the LED element 15 and/or the damage, such as cracking of the LED element 15, can occur.

In this embodiment, by setting the elastic modulus and viscosity of the elastic member 12 to a predetermined value, the elastic member 12 effectively absorbs the kinetic energy E1 of the LED element 15, and the kinetic energy E2 can be made smaller. As a result, the misalignment and the damage of the LED element 15 can be effectively suppressed. In addition, by thermally curing the elastic member 12, the LED element 15 is covered by the elastic member 12 having elasticity. As a result, the elastic member 12 can have the function of protecting the LED element 15 from external force.

In some embodiments, when the elastic member 12 has a height from the substrate 11 being smaller than the LED element 15, a portion of a side of the LED element 15 can be covered by the elastic member 12, and the rest portion of the side of the LED element 15 can be covered by the insulating layer 16.

In some embodiments, when the elastic member 12 has a height from the substrate 11 being same as the LED element 15, a side of the LED element 15 can be entirely covered by the elastic member 12. In this case, only the upper surface of the LED element 15 can be covered by the insulating layer 16.

In addition, the LED elements 15 can be transferred at a pitch different from the pitch of the LED elements 15 on the wafer 5. For example, the LED elements 15 can be transferred to the pitch of the LED elements 15 in the display panel 1 after manufacturing. As a result, a process for converting the pitch of the LED element 15 becomes unnecessary, and manufacturing time can be shortened.

### A Second Embodiment

A method of fabricating a display device according to a second embodiment of the present disclosure will be explained. The method of fabricating the display device according to the second embodiment is different from the first embodiment in that the elastic member 12 is filled with a filler 18 instead of the connection member 14. Hereinafter, the description will focus on the configuration aspects that are different from the first embodiment.

FIG. 6 is a schematic cross-sectional view of a display device according to a second embodiment of the present disclosure. FIG. 6 is a schematic cross-sectional view taken along the line I-I′ in FIG. 1.

The display panel 1 includes a filler 18 without the connection member 14 (of FIG. 2). The filler 18 is filled into the elastic member 12. The filler 18 electrically connects the pad 13 and the terminals 151 and 152. The filler 18 can be disposed between each of the terminals 151 and 152 and the pad 13 so that each of the terminals 151 and 152 and the pad 13 are electrically connected. The filler 18 includes a conductive material. The filler 18 can include a solder-based material. The solder-based material can include a metal such as tin, nickel, copper, antimony, aluminum, zinc, iron, gold, silver, titanium, germanium, tellurium, cobalt, bismuth, manganese, chromium, molybdenum, palladium or indium.

A particle diameter of the filler 18 can be less than or equal to a distance between the terminals 151 and 152. The particle diameter of the filler 18 can be less than the distance between the terminals 151 and 152. For example, the particle diameter of the filler 18 can be 10 μm or less. If the particle diameter of the filler 18 is larger than 10 μm, the filler 18 becomes electrically connected to both the terminal 151 and the terminal 152, and a short circuit can occur.

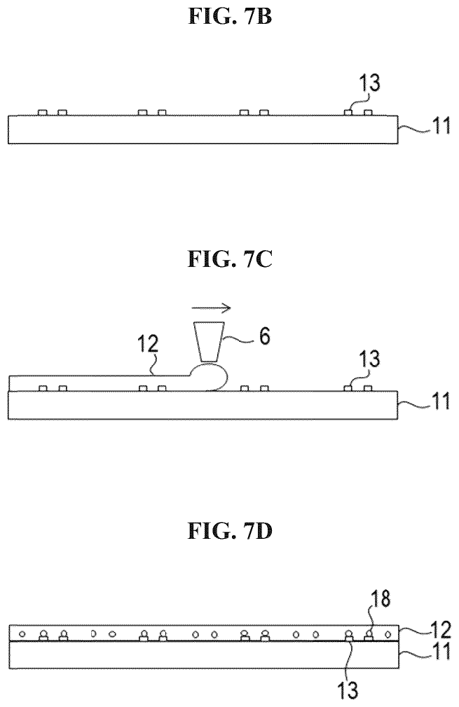

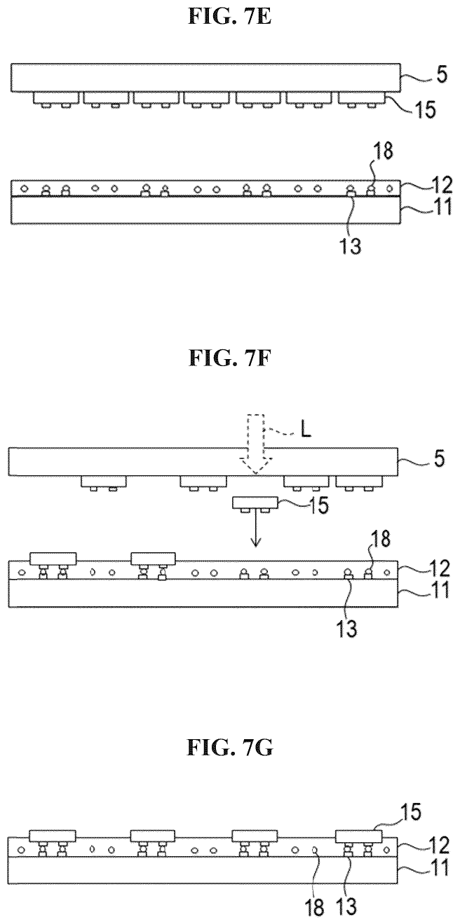

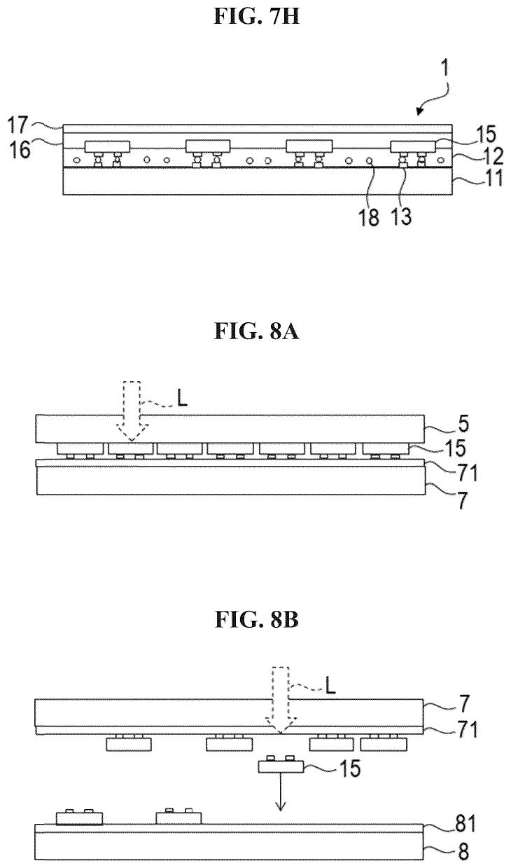

FIGS. 7A to 7H are schematic views illustrating a method of fabricating a display device according to the second embodiment of the present disclosure. FIGS. 7A to 7H shows processes of forming an elastic member 12 including a filler 18, a pad 13, an LED element 15, an insulating layer 16 and a glass substrate 17.

As shown in FIG. 7A, a substrate 11 is prepared. Next, as shown in FIG. 7B, a pad 13 is formed on the substrate 11. Next, as shown in FIG. 7C, an elastic member 12 is formed on the substrate 11. For example, the elastic member 12 can be formed by coating a material using a nozzle 6. Next, as shown in FIG. 7D, the elastic member 12 is filled with the filler 18. The filling of the filler 18 can be performed using a laser beam or can be performed using a nozzle. Alternatively, a mixture including an elastic material and a filler can be coated to form the elastic member 12 including the filler 18. In this case, filling of the filler 18 after the coating of the elastic member 12 is unnecessary.

Next, as shown in FIG. 7E, the wafer 5 is disposed to be opposed to the substrate 11 at a predetermined interval. Next, as shown in FIG. 7F, the LED element 15 is transferred to the substrate 11 by the LLO method. Next, as shown in FIG. 7G, after the transfer of all LED elements 15 is completed, the wafer 5 is separated (or released) from the substrate 11. Next, as shown in FIG. 7H, after the elastic member 12 is thermally cured, an insulating layer 16 and a glass substrate 17 are formed on the elastic member 12 in that order. In this way, the display panel 1 is manufactured.

In the display device of the present disclosure, the elastic resin 12 is formed on the pad 13, and the LED element 15 is transferred into the elastic member 12. As a result, a portion of the elastic member 12 is presented between the pads 13 for a single LED element 15. Namely, a portion of the elastic member 12 is presented in a space formed by the pads 13 and the LED element 15.

In the display device of this embodiment, the elastic member 12 can effectively absorb the kinetic energy of the LED element 15. Accordingly, the misalignment and damage of the LED element 15 can be suppressed. In addition, in the display device of this embodiment, instead of forming the connecting member 14 on the pad 13, the elastic member 12 is filled with the filler 18. Accordingly, when the process of forming the connection member 14 on the pad 13 is complicated, the configuration in this embodiment can be effective. Namely, a fabrication method of the display device can be simplified.

### A Third Embodiment

A method of fabricating a display device according to a third embodiment of the present disclosure will be explained.

The fabricating method of the display device in this embodiment is different from the first embodiment in that a pitch conversion substrate is prepared. Hereinafter, the description will focus on the configuration different from the first embodiment.

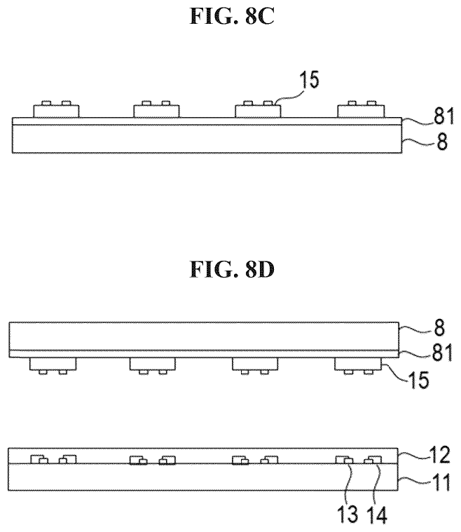

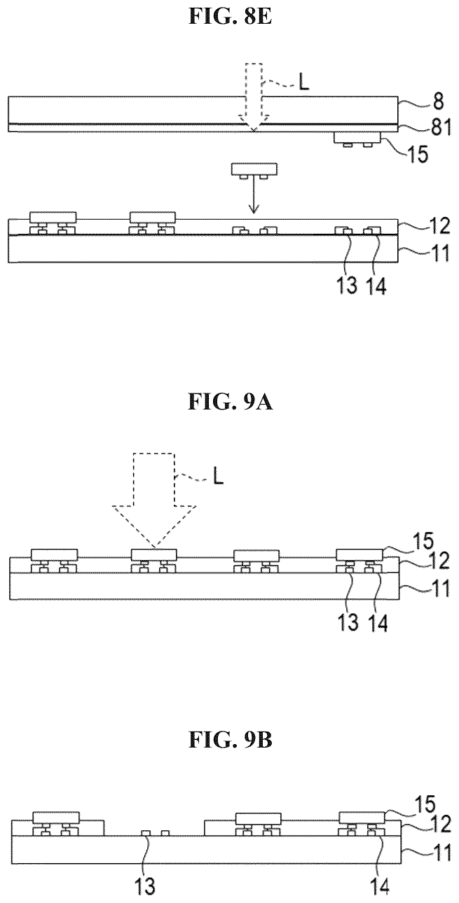

FIGS. 8A to 8E are schematic views illustrating a method of fabricating a display device according to a third embodiment of the present disclosure. FIGS. 8A to 8E shows processes of transferring an LED element from a pitch conversion substrate.

As shown in FIG. 8A, a laser beam L is irradiated from the back of the wafer 5 to the LED element 15, and the LED element 15 is transferred to a temporary substrate 7. The temporary substrate 7 is made of a rigid material such as glass. An adhesive member 71 can be formed on an upper surface of the temporary substrate 7. Namely, the LED element 15 can be transferred onto the adhesive member 71 on the temporary substrate 7. The adhesive member 71 can be a pressed resin material, an adhesive material, an adhesive tape, or the like. The wafer 5 and the temporary substrate 7 are positioned by a stage that can be raised and lowered. The distance between the LED element 15 and the adhesive member 71 can be set to a predetermined distance by the stage.

Next, as shown in FIG. 8B, a laser beam L is irradiated from the back of the temporary substrate 7 to the LED element 15, and the LED element 15 is transferred from the temporary substrate 7 onto a pitch conversion substrate 8. The pitch conversion substrate 8 is made of a rigid material such as glass. An adhesive member 81 can formed on an upper surface of the pitch conversion substrate 8. Namely, the LED element 15 can be transferred onto the adhesive member 81 on the pitch conversion substrate 8. The adhesive member 81 can be a pressed resin material, an adhesive material, an adhesive tape, or the like. The laser beam L is irradiated onto the LED elements 15 at a pitch different from a pitch of the LED elements 15 on the temporary substrate 7. As a result, the pitch of the LED elements 15 transferred to the pitch conversion substrate 8 can be changed from the pitch of the LED elements 15 on the temporary substrate 7.

Next, as shown FIG. 8C, after the transfer of the LED element 15 is completed, the temporary substrate 7 is separated (or released) from the pitch conversion substrate 8. In this way, the LED element 15 is formed on the pitch conversion substrate 8.

Next, as shown in FIG. 8D, the pitch conversion substrate 8 is disposed to be opposed to the substrate 11 at a predetermined interval. In FIG. 8D, an elastic member 12, a pad 13, and a connection member 14 are formed on the substrate 11. Next, as shown in FIG. 8E, the LED element 15 is transferred to the substrate 11 by the LLO method.

In the display device of this embodiment, the elastic member 12 can effectively absorb the kinetic energy of the LED element 15. Accordingly, the misalignment and damage of the LED element 15 can be suppressed. In addition, in the display device of this embodiment, the LED element 15 is transferred by using the pitch conversion substrate 8. Accordingly, when the process of directly transferring the LED elements 15 from the wafer 5 to the substrate 11 and arranging the LED elements 15 at a desired pitch is complicated, the configuration in this embodiment can be effective.

### A Fourth Embodiment

A method of fabricating a display device according to a fourth embodiment of the present disclosure will be explained.

The fabricating method of the display device in the present embodiment is different from the first embodiment in a repair process for the LED element 15. Hereinafter, the description will focus on the configuration different from the first embodiment.

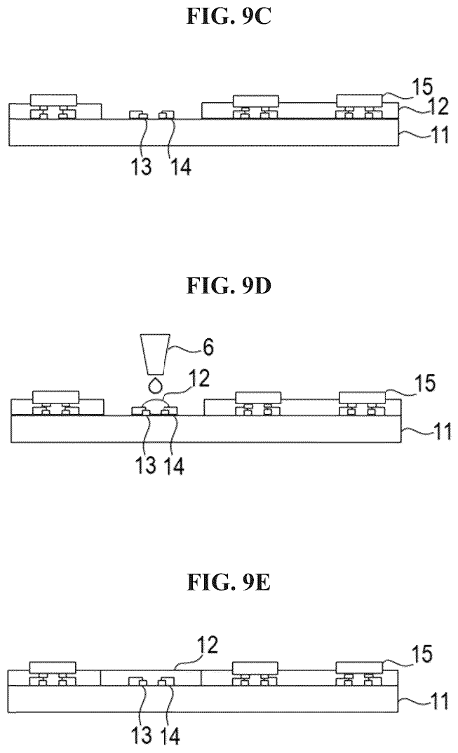

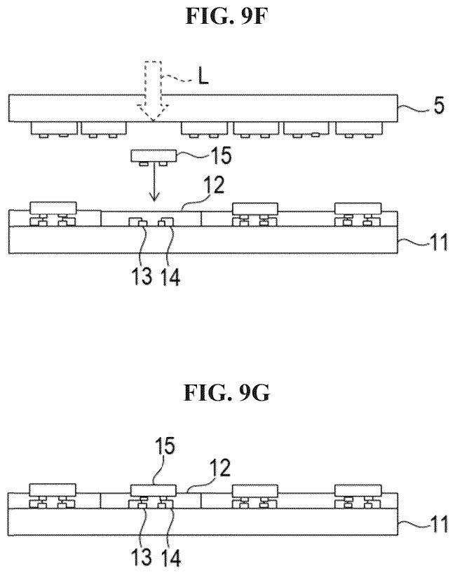

FIGS. 9A to 9G are schematic views illustrating a method of fabricating a display device according to a fourth embodiment of the present disclosure.

FIGS. 9A to 9G show the repair process of the LED element 15. The repair process can be performed after transferring the LED element 15 to the substrate 11 and before forming the insulating layer 16 on the elastic member 12.

As shown in FIG. 9A, laser beam L is irradiated to the LED element 15 that has been transferred with a misaligned position. As shown in FIG. 9B, the LED element 15, the connection member 14, and the elastic member 12 are removed by irradiation of the laser beam L.

As shown in FIG. 9C, a new connection member 14 is formed on the pad 13. The new connection member 14 can be formed by a nozzle, or can be formed by flying the connection member 14 from another substrate onto the pad 13 by LLO. Next, as shown in FIG. 9D, an elastic member 12 is formed on the connection member 14 using the nozzle 6. The elastic member 12 can be filled with a filler. As shown in FIG. 9, a thickness of the elastic member 12 filled is preferably equal to a thickness of the surrounding elastic member 12. Next, as shown in FIG. 9F, the LED element 15 is transferred from the wafer 5 to the substrate 11 by the LLO method. Next, as shown in FIG. 9G, the elastic member 12 is cured by heat or the like to remove the LED element 15 to be repaired, and the LED element 15 can be newly transcribed.at the desired position.

In this embodiment, by setting the elastic modulus and viscosity of the elastic member 12 to a predetermined value, the elastic member 12 effectively absorbs the kinetic energy E1 of the LED element 15. As a result, the misalignment and the damage of the LED element 15 can be effectively suppressed, and the time for the repairing process of the LED element 15 can be reduced.

In addition, by thermally curing the elastic member 12, the LED element 15 is covered by the elastic member 12 having elasticity. As a result, the elastic member 12 can have the function of protecting the LED element 15 from external force. For example, a portion of a side of the LED element 15 can be covered by the elastic member 12, and the rest portion of the side of the LED element 15 can be covered by the insulating layer 16.

Moreover, the repair process according to this embodiment can be applied to a conventional display panel fabricating process. For example, a conventional display panel has LED elements 15 formed on an anisotropic conductive film (ACF) instead of the elastic member 12. When the repair process according to the present embodiment is applied to such a display panel, the display panel after repair includes the LED element 15 installed on the ACF and the LED element 15 installed on the elastic member 12.

The storage modulus, the loss modulus and the viscosity may be measured by a suitable technique known in the art.

For instance, the storage modulus, often denoted as G′G′G′ for shear or EE′E′ for tensile/compressive measurements, is a measure of a material's elastic response when subjected to a cyclic or oscillating stress. It can be measured using dynamic mechanical analysis (DMA), a technique used to assess the viscoelastic properties of materials, especially polymers. In DMA, a sample of the material is prepared in a standard geometry (e.g., rectangular, cylindrical). The sample is placed in the DMA instrument, which has a mechanism to apply cyclic stress or strain, e.g., a small oscillatory or sinusoidal stress or strain to the sample at a set frequency. As the sample deforms, it stores part of the energy elastically (storage modulus) and dissipates part of the energy as heat (loss modulus). The DMA measures the resulting strain in response to the applied stress. The storage modulus G′G′G′ (or E′E′E′ in tension) is calculated as the in-phase component of the stress-strain response, representing the elastic, energy-storing portion of the material's response. The DMA software calculates G′G′G′ or E′E′E′ from the amplitude and phase angle difference between the stress and strain. The storage modulus is often measured over a range of temperatures and frequencies, as viscoelastic materials typically show temperature and frequency-dependent behavior. The value of G′G′G′ or E′E′E′ relates to the stiffness and rigidity of the material under dynamic conditions, helping to characterize materials in applications where they experience cyclic loading, like in tires or damping materials.

The loss modulus, often denoted as G″G″G″ for shear or E″E″E″ for tensile/compressive measurements, represents the viscous or energy-dissipative component of a material's response to an oscillatory stress or strain. Like the storage modulus, it is typically measured using dynamic mechanical analysis (DMA). The sample is prepared in a specific shape and mounted in the DMA instrument, similar to how it would be for measuring the storage modulus. A sinusoidal or oscillatory stress or strain is applied to the sample at a controlled frequency. As the sample deforms, it exhibits both an elastic (storage) and a viscous (loss) response. The DMA measures the stress and strain signals and calculates the phase lag (phase angle), δ\deltaδ, between them. The loss modulus G″G″G″ or E″E″E″ is then determined from the out-of-phase component of the stress-strain response, which corresponds to the viscous, energy-dissipative part. Like the storage modulus, the loss modulus can be measured across a range of temperatures and frequencies to characterize the material's viscoelastic behavior under various conditions.

In some embodiments, the viscosity is measured at a temperature: 20° C. to 100° C., a pressure at atmospheric pressure or a high pressure (1-1000 bar for specialized applications), and a shear rate of 0.1 to 1000 s⁻¹ (for Newtonian fluids), or up to 100,000 s⁻¹ for non-Newtonian fluids. The viscosity can be measured using any suitable technique. For instance: a rotational viscometer method (e.g., measuring the torque needed to turn an object that's been placed in the sample fluid being tested), a capillary viscometer method (e.g., measuring the time for a volume of liquid to mass through the length of a capillary tube such as an Ostwald or Ubbelohde viscometer), a falling sphere viscometer method (e.g., measuring viscosity by dropping a sphere or piston of a known density through a sample liquid and measuring how long it takes to fall), a vibrational viscometer meter method (e.g., where an oscillating electromechanical resonator is immersed in the fluid sample and the degree of damping the fluid offers is measured), a viscosity cup method (e.g., putting the sample in a container with a hole in the bottom then measuring the time it takes to fill a cup placed below it).

### EXAMPLES

The following examples are exemplary and not intended to be limiting. The above disclosure provides many different embodiments for implementing the features of the invention, and the following examples describe certain embodiments. It will be appreciated that other modifications and methods known to one of ordinary skill in the art can also be applied to the following experimental procedures, without departing from the scope of the invention.

Hereinafter, the experimental results of the elastic member according to the embodiment of the present invention will be described.

TABLE 1

| | | | storage | loss | | |
|---|---|---|---|---|---|---|
| | A | B | modulus | modulus | viscosity | |
| | [g] | [g] | [Pa] | [Pa] | [Pa · s] | Evalution |
| Ex1 | 4.0548 | 10.0091 | 0.01538 | 12.91 | 2.054 | OK |
| Ex2 | 5.4943 | 10.0031 | 0.0322 | 18.98 | 3.02 | OK |
| Ex3 | 6.9336 | 10.0073 | 0.09388 | 19.21 | 3.057 | OK |
| Ex4 | 8.3749 | 10.0048 | 0.09388 | 29.62 | 4.714 | OK |
| Ex5 | 9.8113 | 10.0033 | 0.1298 | 35.26 | 5.612 | OK |
| Ref1 | 2.6115 | 10.0061 | 0.00298 | 9.745 | 1.551 | NG |

Table 1 shows the storage modulus (Pa), the loss modulus (Pa) and the viscosity (Pa s) of the elastic member before thermal curing process, the amount (g) of material A, the amount (g) of material B, and the evaluation result of misalignment and damage of LED elements in Examples 1 to 5 and Comparative Example 1. In Examples 1 to 5 and Comparative Example 1, the thickness of the elastic member was 5 μm. The storage modulus and the loss modulus were measured by dynamic viscoelasticity measurement. In addition, the viscosity was measured using a vibrating viscometer or tuning fork vibrating viscometer according to JISZ8803:2011.

The “Evaluation” in Table 1 indicates whether misalignment and damage (e.g., breakage) of LED elements are suppressed or not when a display device is manufactured using the elastic members according to Examples 1 to 5 and Comparative Example 1. When the misalignment and damage of the LED elements are sufficiently suppressed, the evaluation is judged as good (OK). When the misalignment and damage of the LED elements are not sufficiently suppressed, the evaluation is judged as bad (NG).

In Example 1 (Ex1), the content of material A was 4.0548 g, and the content of material B was 10.0091 g. The storage modulus of the elastic member was 0.01538 Pa. The loss modulus of the elastic member was 12.91 Pa. The viscosity of the elastic member was 2.054 Pa s. The ratio of LED elements that were misaligned and damaged satisfied the standards, and the evaluation was good (OK).

In Example 2 (Ex2), the content of material A was 5.4943 g, and the content of material B was 10.0031 g. The storage modulus of the elastic member was 0.0322 Pa. The loss modulus of the elastic member was 18.98 Pa. The viscosity of the elastic member was 3.02 Pa s. The ratio of LED elements that were misaligned and damaged satisfied the standards, and the evaluation was good (OK).

In Example 3 (Ex3), the content of material A was 6.9336 g, and the content of material B was 10.0073 g. The storage modulus of the elastic member was 0.04773 Pa. The loss modulus of the elastic member was 19.21 Pa. The viscosity of the elastic member was 3.057 Pa s. The ratio of LED elements that were misaligned and damaged satisfied the standards, and the evaluation was good (OK).

In Example 4 (Ex4), the content of material A was 8.3749 g, and the content of material B was 10.0048 g. The storage modulus of the elastic member was 0.09388 Pa. The loss modulus of the elastic member was 29.62 Pa. The viscosity of the elastic member was 4.714 Pa s. The ratio of LED elements that were misaligned and damaged satisfied the standards, and the evaluation was good (OK).

In Example 5 (Ex5), the content of material A was 9.8113 g, and the content of material B was 10.0033 g. The storage modulus of the elastic member was 0.1298 Pa. The loss modulus of the elastic member was 29.62 Pa. The viscosity of the elastic member was 4.714 Pa s. The ratio of LED elements that were misaligned and damaged satisfied the standards, and the evaluation was good (OK).

In Comparative Example 1 (Ref1), the content of material A was 2.6115 g, and the content of material B was 10.0061 g. The storage modulus of the elastic member was 0.00298 Pa. The loss modulus of the elastic member was 9.745 Pa. The viscosity of the elastic member was 1.551 Pa s. The proportion of LED elements that were misaligned or damaged did not meet the standards, and the evaluation was poor (NG).

As described above, according to the present embodiment, a method of fabricating a display device capable of suppressing misalignment and damage of the light emitting element can be provided.

In addition, the elastic member 12 preferably has a storage modulus of 0.01 Pa or more, a loss modulus of 10.0 Pa or more, and a viscosity of 1.8 Pa·sor more. Accordingly, the elastic member 12 can effectively absorb the kinetic energy of the LED element 15.

Moreover, the thickness of the elastic member 12 is preferably less than or equal to the height of the LED element 15, and the thickness of the elastic member 12 is preferably 10 μm or less, more preferably 5 μm or less. Thereby, the elastic member 12 can absorb the kinetic energy of the LED element 15 more effectively.

Furthermore, the elastic member 12 preferably has a storage modulus of 100 Pa or less and a loss modulus of 1000 Pa or less. Thereby, the elastic member 12 can absorb the kinetic energy of the LED element 15 more effectively.

It will be apparent to those skilled in the art that various modifications and variations can be made in the present disclosure without departing from the spirit or scope of the present disclosure. Thus, it is intended that the present disclosure cover the modifications and variations of this disclosure provided they come within the scope of the appended claims and their equivalents.

What is claimed is:

1. A method of fabricating a display device, the method comprising:
providing a first light emitting element on a first substrate;
providing a first elastic member on a second substrate;
disposing the first substrate including the first light emitting element over the second substrate including the first elastic member, wherein the elastic member faces the first light emitting element; and
transferring the first light emitting element from the first substrate onto the second substrate by irradiating a laser beam,
wherein the first elastic member has a storage modulus of 0.01 Pa or more, a loss modulus of 10.0 Pa or more, and a viscosity of 1.8 Pa·s or more.

2. The method according to claim 1, wherein a thickness of the first elastic member is equal to or smaller than a thickness of the first light emitting element.

3. The method according to claim 1, wherein the storage modulus of the first elastic member is 100 Pa or less.

4. The method according to claim 1, wherein the loss modulus of the first elastic member is 1000 Pa or less.

5. The method according to claim 1, wherein the viscosity of the first elastic member is 5.612 Pa·s or less.

6. The method according to claim 1, wherein the first elastic member includes a thermosetting resin.

7. The method according to claim 6, wherein the thermosetting resin includes at least one of an acrylic compound, a silicone compound, an epoxy compound, an epoxyacrylate compound, an oxetane compound, an episulfide compound, an acrylic silicone compound, a methacrylic compound, a phenol compound, an amino compound, an unsaturated polyester compound, or a polyurethane compound.

8. The method according to claim 7, wherein the acrylic compound is represented by Formula 1, Formula 2, or Formula 3: 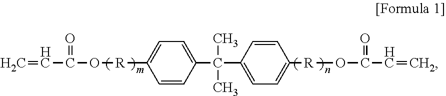
wherein in Formula 1, R independently represents an organic group, and each of m and n independently represents an integer of 0 or more, 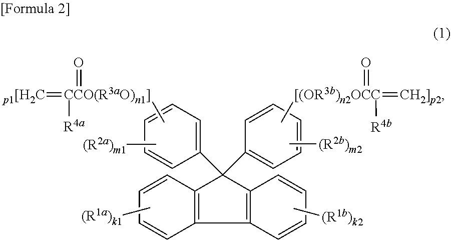
wherein in Formula 2, each of R^{1a}, R^{1b}, R^{2a}, R^{2b}, R^{3a}, R^{3b}, R^{4a} and R^{4b} independently represents a hydrogen atom or an organic group, and each of k1, k2, m1, m2, n1, n2, p1 and p2 independently represents an integer of 0 or more, 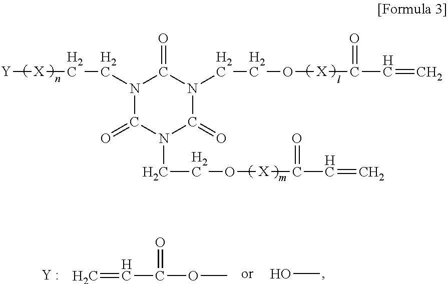
wherein in Formula 3, X independently represents an organic group, and each of l, m and n independently represents integers of 0 or more,
wherein the silicon compound is represented by Formula 4: 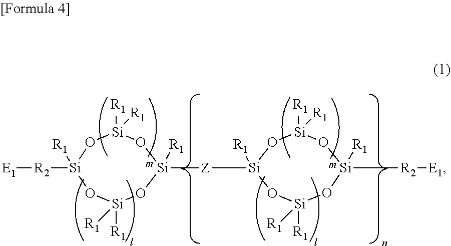
wherein in Formula 4, each of R₁, R₂ and E₁ independently represents a hydrogen atom or an organic group, Z represents an organic group, and each of l, m, and n independently represents an integer of 0 or more,
wherein the silicon compound is a compound of Formula 5: 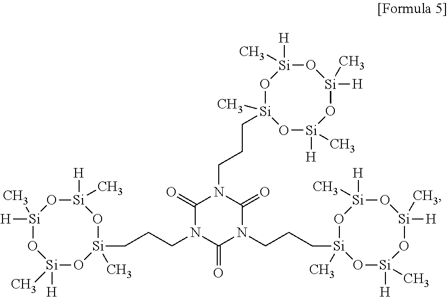 [SMILES: C[SiH]1O[SiH](C)O[Si](C)(CCCn2c(=O)n(CCC[Si]3(C)O[SiH](C)O[SiH](C)O[SiH](C)O3)c(=O)n(CCC[Si]3(C)O[SiH](C)O[SiH](C)O[SiH](C)O3)c2=O)O[SiH](C)O1]
wherein the epoxy compound is represented by Formula 6: 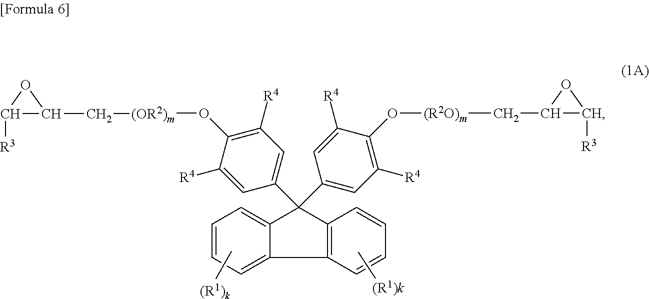
wherein in Formula 6, each of R¹, R², R³ and R⁴ independently represents a hydrogen atom or an organic group, and each of k and m independently represents an integer of 0 or more, or
wherein the epoxy compound is a compound of Formula 7:

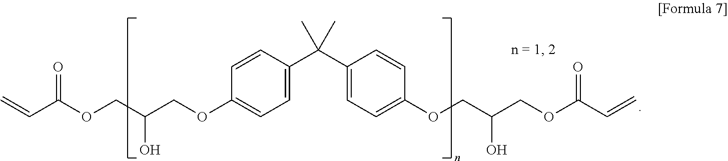

9. A method of transferring a light emitting element, the method comprising:
providing a first light emitting element on a first substrate;
providing a first elastic member on a second substrate;
disposing the first substrate including the first light emitting element over the second substrate including the first elastic member, wherein the elastic member faces the first light emitting element; and
transferring the first light emitting element from the first substrate onto the second substrate,
wherein the first elastic member has a storage modulus of 0.01 Pa or more, a loss modulus of 10.0 Pa or more, and a viscosity of 1.8 Pa·s or more.

10. The method according to claim 9, wherein the transferring comprises irradiation on the first substrate by a laser beam, wherein the laser beam is a gas laser, a solid-state laser, an excimer laser, a diode laser, a fiber laser, a dye laser, or an ion laser.

11. The method according to claim 10, wherein the laser beam is operated using at least one of the following parameters: a wavelength from about 300 nm to about 500 nm; a pulse duration of about 10-100 ns, a pulse energy of about 1-50 J per pulse, a spot size of 5-30 m, a repetition rate of 1-10 Hz.

12. The method according to claim 9, wherein the first light emitting element is an standard light emitting diode (LED), a miniature LED, a micro LED, a high-power LED, a RGB (red green blue) LED, a surface-mount LED, a chip-on-board LED, an organic LED (OLED), an infrared (IR) LED, an ultraviolet (UV) LED, or a flash LED.

13. The method according to claim 1, wherein the first substrate is a sapphire substrate.

14. The method according to claim 1, wherein a pitch of the first light emitting element on the first substrate is different from a pitch of the first light emitting element on the second substrate.

15. The method according to claim 1, further comprising:
providing a connection member on the second substrate before the step of providing the first elastic member,
wherein the first light emitting element and the second substrate are electrically connected to each other by the connecting member.

16. The method according to claim 1, further comprising:
filling the first elastic member with a filler before the step of transferring the first light emitting element,
wherein the first light emitting element and the second substrate is electrically connected to each other by the filler.

17. The method according to claim 1, wherein the first light emitting element is formed on the first substrate by transferring the first light emitting element on a temporary substrate onto the first substrate.

18. The method according to claim 1, further comprising:
removing the first light emitting element and the first elastic member in a region and on the second substrate after the step of transferring the first light emitting element;
providing a second elastic member in the region and on the second substrate;
disposing a third substrate including a second light element over the second substrate; and
transferring the second light emitting element from the third substrate onto the second substrate by irradiating a laser beam.

19. A display device, comprising:
a substrate;
an elastic member on the substrate; and
a light emitting element on the elastic member,
wherein the elastic member has a storage modulus of 0.01 Pa or more, a loss modulus of 10.0 Pa or more.

20. The display device according to claim 19, wherein a height of the elastic member is equal to or smaller than the light emitting element.
